(19) United States
(12) Patent Application Publication
(10) Pub. No.: US 2012/0202060 A1
(43) Pub. Date: Aug. 9, 2012

(54) NANOTUBE-NANOHORN COMPLEX AND METHOD OF MANUFACTURING THE SAME

(75) Inventors: Ryota Yuge, Tokyo (JP); Masako Yudasaka, Tokyo (JP)

(73) Assignee: NEC CORPORATION, Minato-ku, Tokyo (JP)

(21) Appl. No.: 13/502,055

(22) PCT Filed: Oct. 6, 2010
(86) PCT No.: PCT/JP2010/067990

§ 371 Date: Apr. 13, 2012

(30) Foreign Application Priority Data
Oct. 16, 2009 (JP) 2009-238936

(51) Int. Cl. D01F 9/12; C23C 14/34; B82Y 30/00; B82Y 40/00

(52) U.S. Cl. 428/367; 423/447.2; 204/192.11; 977/742; 977/750; 977/752; 977/844

(57) ABSTRACT

An object of the present invention is to provide a nanotube-nanohorn complex having a high aspect ratio, also having high dispersibility, having controlled diameter, and having high durability at a low cost. According to the present invention, a carbon target containing a catalyst is evaporated with a laser ablation method to synthesize a structure including both of a carbon nanohorn aggregate and a carbon nanotube.

### BACKGROUND OF THE INVENTION

The present invention relates to a nanotube-nanohorn complex and a method of manufacturing the same.

Carbon nanotubes comprise such characteristics that they have a high aspect ratio, are chemically stable, and are mechanically strong. Therefore, carbon nanotubes have greatly been expected as field emission luminous elements as disclosed in Japanese laid-open patent publications Nos. 2001-143645 (Patent Literature 1) and 2000-86219 (Patent Literature 2) and have diligently been studied.

In most cases where carbon nanotubes are used as field emission elements as disclosed in Japanese laid-open patent publications No. 2007-103313 (Patent Literature 3) and 2007-265749 (Patent Literature 4), it has been customary to mix a binder or the like so as to produce paste for application onto an electrode by spraying, screen printing, or the like. However, the dispersibility of carbon nanotubes is so poor that homogeneous paste cannot be obtained. Accordingly, there has been a large problem in uniformity of the light emission.

Aggregates of carbon nanohorns, which comprise a horn structure with a sheath structure like a carbon nanotube and a closed end, have been found in recent years. The unique structure of a carbon nanohorn has industrially attracted attention as a fuel cell as shown in Japanese laid-open patent publication No. 2002-159851 (Patent Literature 5) or a catalyst carrier for steam reforming to produce hydrogen from hydrocarbon such as methane as shown in disclosed in Japanese laid-open patent publication No. 2007-7599 (Patent Literature 6). Recently, carbon nanohorns have also greatly been expected as field emission elements as disclosed in Japanese laid-open patent publications Nos. 2003-77385 (Patent Literature 7) and 2009-76314 (Patent Literature 8).

It has already been known that carbon nanohorns are nanocarbon having high conductivity because they comprise a tubular structure. Carbon nanohorns are spherical aggregates having a diameter of 1 nm to 5 nm in which the length of a sheath comprising a horn structure is in a range of 30 nm to 200 nm. Although carbon nanohorns have higher dispersibility than carbon nanotubes, an aspect ratio of carbon nanohorns is so low that carbon nanohorns are unsuitable to field emission elements and the like.

In Japanese patent application No. 2008-169942 (Patent Literature 9), the applicant has proposed a nanotube-nanohorn complex having a high aspect ratio, also having high dispersibility, and allowing a carbon nanotube to grow with controlled diameter.

### SUMMARY OF THE INVENTION

The nanotube-nanohorn complex described in Patent Literature 9 is an excellent invention in that it has a high aspect ratio, also high dispersibility, and allowing a carbon nanotube to grow with controlled diameter.

In order to produce the nanotube-nanohorn complex described in Patent Literature 9, however, carbon nanotubes should be synthesized from catalyst-carried carbon nanohorns by a chemical vapor deposition method (CVD method). Thus, there is a room for further improvement in cost reduction and mass synthesis. Additionally, a CVD method has a low synthesis temperature, resulting in low crystallinity. Thus, there is also a room for improvement in durability as a field emission element.

The invention of the present application has been made in view of the foregoing circumstances. It is, therefore, an object of the invention to solve problems in the prior art and to provide a nanotube-nanohorn complex having a high aspect ratio, also having high dispersibility, allowing a carbon nanotube to grow with controlled diameter, and having high durability at a low cost.

Therefore, in order to solve the above problems, the invention of the present application comprises the following features.

Specifically, a first aspect of the invention of the present application is a nanotube-nanohorn complex wherein a carbon nanotube grows from a catalyst, which is surrounded by a carbon nanohorn aggregate.

Furthermore, a second aspect of the invention of the present application is a method of manufacturing a nanotube-nanohorn complex, the method comprising evaporating a carbon target containing a catalyst with a laser ablation method to synthesize a structure including both of a carbon nanohorn aggregate and a carbon nanotube.

Moreover, a third aspect of the invention of the present application is a method of manufacturing a nanotube-nanohorn complex, the method comprising evaporating a carbon target containing a catalyst with a laser ablation method to synthesize a structure in which a carbon nanotube grows from the catalyst, which is surrounded by a carbon nanohorn aggregate.

Furthermore, a fourth aspect of the invention of the present application is a paste for field emission comprising the nanotube-nanohorn complex as recited in the first aspect.

Moreover, a fifth aspect of the invention of the present application is a cold cathode electron source comprising the paste for field emission as recited in the third aspect.

Furthermore, a sixth aspect of the invention of the present application is a light emitting device using the cold cathode electron source as recited in the fourth aspect.

Moreover, a seventh aspect of the invention of the present application is an illuminating apparatus using the light emitting device as recited in the fifth aspect.

Furthermore, an eighth aspect of the invention of the present application is a light emitting method using the illuminating apparatus as recited in the sixth aspect.

### EFFECT(S) OF THE INVENTION

According to the invention of the present application, there can be provided a nanotube-nanohorn complex having a high aspect ratio, also having high dispersibility, allowing a carbon nanotube to grow with controlled diameter, and having high durability at a low cost.

### BRIEF DESCRIPTION OF DRAWINGS

FIG. 1A is a diagram simulating a transmission electron microscope photograph of a nanotube-nanohorn complex 1 according to an embodiment of the present invention.

FIG. 1B is a diagram simulating a transmission electron microscope photograph of a nanotube-nanohorn complex 1 according to an embodiment of the present invention.

FIG. 1C is a conceptual diagram of a nanotube-nanohorn complex 1 according to an embodiment of the present invention.

FIG. 1D is a conceptual diagram of the nanotube-nanohorn complex 1 according to an embodiment of the present invention.

FIG. 1E is a conceptual diagram of the nanotube-nanohorn complex 1 according to an embodiment of the present invention.

FIG. 1F is a conceptual diagram of the nanotube-nanohorn complex 1 according to an embodiment of the present invention.

FIG. 1G is a conceptual diagram of the nanotube-nanohorn complex 1 according to an embodiment of the present invention.

FIG. 1H is a conceptual diagram of the nanotube-nanohorn complex 1 according to an embodiment of the present invention.

FIG. 2A is a Raman spectrum illustrating the CO₂ laser output dependency of a sample produced in Example 1.

FIG. 2B is a Raman spectrum illustrating the CO₂ laser output dependency of a sample produced in Example 1.

FIG. 3A is a diagram simulating a transmission electron microscope photograph of a sample produced in Example 1.

FIG. 3B is a diagram simulating a transmission electron microscope photograph of a sample produced in Example 1.

FIG. 3C is a diagram simulating a transmission electron microscope photograph of a sample produced in Example 1.

FIG. 3D is a diagram simulating a scanning electron microscope photograph of a sample produced in Example 1.

FIG. 4A is a Raman spectrum illustrating the Ar pressure dependency of a sample produced in Example 2.

FIG. 4B is a Raman spectrum illustrating the Ar pressure dependency of a sample produced in Example 2.

FIG. 5A is a diagram simulating a transmission electron microscope photograph of a sample produced under conditions with an Ar pressure of 500 Torr (667×10² Pa) among samples produced in Example 2.

FIG. 5B is a diagram simulating a transmission electron microscope photograph of a sample produced under conditions with an Ar pressure of 500 Torr (667×10² Pa) among samples produced in Example 2.

FIG. 6A is a diagram simulating a transmission electron microscope photograph of a sample produced under conditions with an Ar pressure of 760 Torr (1013×10² Pa) among samples produced in Example 2.

FIG. 6B is a diagram simulating a transmission electron microscope photograph of a sample produced under conditions with an Ar pressure of 760 Torr (1013×10² Pa) among samples produced in Example 2.

FIG. 7A is a Raman spectrum illustrating the catalyst dependency of a sample produced in Example 3.

FIG. 7B is a Raman spectrum illustrating the catalyst dependency of a sample produced in Example 3.

FIG. 8 is a Raman spectrum illustrating the Ar—Kr gas atmosphere dependency of a sample produced in Example 4.

FIG. 9 is a measurement result of field electron emission characteristics of a nanotube-nanohorn complex (NTNH) produced in Example 5, along with field electron emission characteristics of a carbon nanohorn (CNH) for purposes of comparison.

### DESCRIPTION OF REFERENCE NUMERALS

1 nanotube-nanohorn complex
100 carbon nanohorn aggregate
101 catalyst
102 carbon nanotube
103 graphene
104 carbon nanohorn

### MODE(S) FOR CARRYING OUT THE INVENTION

The invention of the present application comprises features as described above. Embodiments of the present invention will be described below.

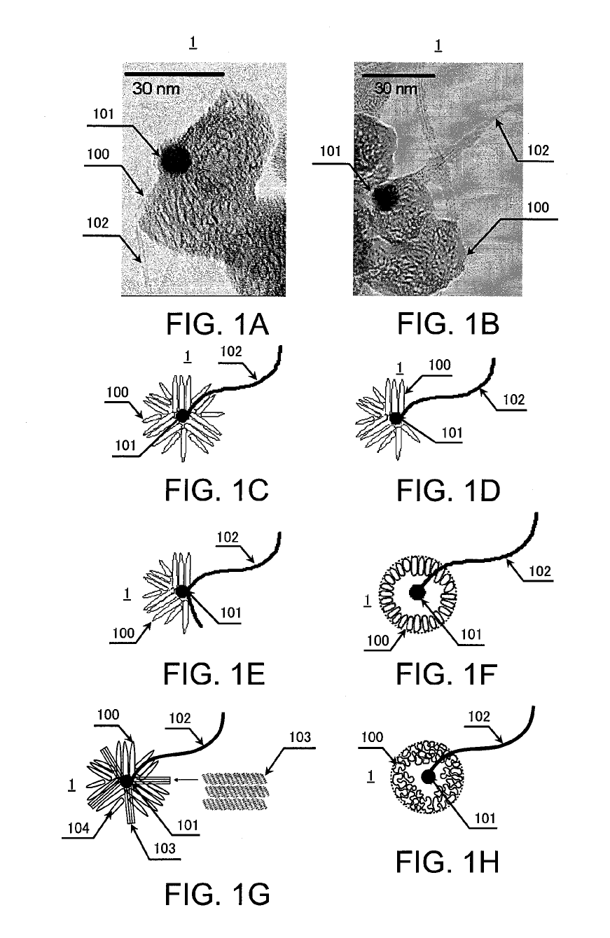

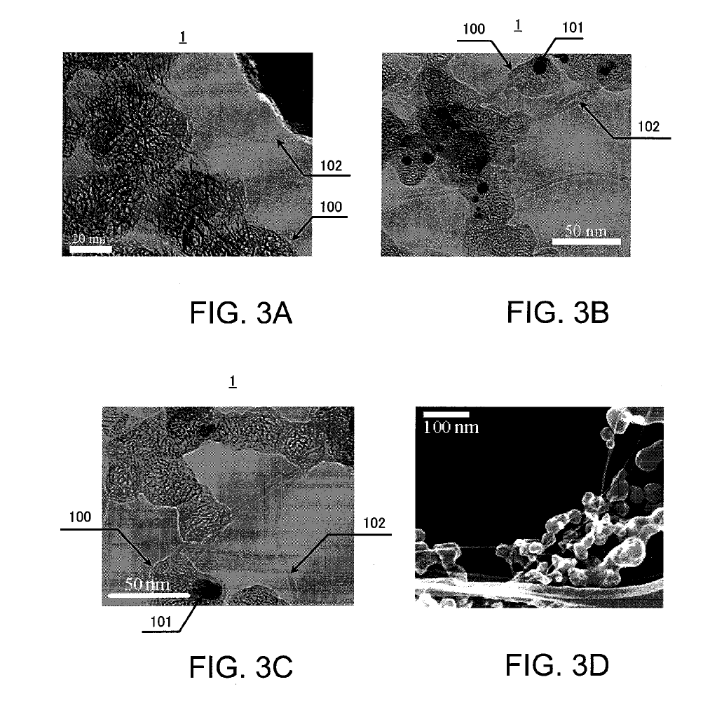

An outlined structure of a nanotube-nanohorn complex 1 according to the present embodiment will be described with reference to FIGS. 1A to 1H and 3A to 3D.

Referring to FIGS. 1A and 1B, a nanotube-nanohorn complex 1 comprises a feature in which a carbon nanotube 102 grows from a catalyst 101, which is surrounded by a carbon nanohorn aggregate 100. Furthermore, as shown in FIGS. 3A to 3D, the carbon nanohorn aggregate 100 coexists with the carbon nanotube 102. Moreover, the carbon nanotube 102 has substantially the same diameter, which can be controlled by manufacturing conditions described later.

At that time, as shown in the conceptual diagrams of FIGS. 1C, 1D, 1E, and 1F, the carbon nanohorn aggregate 100 comprises a dahlia-like form (FIGS. 1C, 1D, and 1E) or a bud-like form (FIG. 1F), or may comprise a petal-like form shown in FIG. 1G or a seed-like form shown in FIG. 1H. The petal-like form refers to a structure in which graphene 103 and carbon nanohorns 104 arbitrarily gather and aggregate. The carbon nanotube 102 grows from the catalyst. The number and diameter of carbon nanotubes 102 can be controlled by manufacturing conditions. The carbon nanotube 102 can grow with a single layer, two layers, or multiple layers (three or more layers). In FIGS. 1C to 1H, the catalyst is positioned at the center of the carbon nanohorn aggregate 100. Nevertheless, the catalyst may be deviated from the center of the carbon nanohorn aggregate 100.

Furthermore, the carbon nanotube 102 preferably has the following size in view of limitation on a manufacturing process or a size with which the carbon nanotube 102 can be synthesized: In the case of a single layer, the diameter is in a range of 0.4 nm to 4 nm. In the case of two layers, the inside diameter is in a range of 0.4 nm to 20 nm, and the outside diameter is in a range of 0.7 nm to 22 nm. In the case of multiple layers, the inside diameter is in a range of 0.4 nm to 200 nm, and the outside diameter is in a range of 0.7 nm to 500 nm.

Next, a method of manufacturing a nanotube-nanohorn complex 1 according to the present embodiment will be described.

A method of manufacturing a nanotube-nanohorn complex 1 according to an embodiment of the present invention is not limited to a specific one as long as it produces the aforementioned structure. Nevertheless, the aforementioned structure is suitably synthesized by evaporating a carbon target containing a catalyst with a laser ablation method.

Specific manufacturing methods will be described below.

### [Laser and Irradiation Conditions]

A CO₂ laser, a YAG (Yttrium Aluminum Garnet) laser, or an excimer laser can be used as a laser for the laser ablation. A CO₂ laser is the most suitable one for the following reasons: A CO₂ laser utilizes transitions of vibrational and rotational levels of CO₂ molecules. The quantum efficiency is about 40% to about 50% and is thus very high. Furthermore, the oscillation efficiency is high. Therefore, an output of the laser can readily be increased. Thus, a CO₂ laser is suitable for evaporation of a carbon target. An output of 1 kW/cm² to 1000 W/cm² can be used for CO₂ laser ablation, which can be performed by continuous irradiation and pulse irradiation. Furthermore, the synthesis can continuously be performed by rotating a target. At that time, it is the most effective to set a laser output to be 30 kW/cm² to 50 kW/cm². If a laser output is lower than 15 kW/cm², then a target is hardly evaporated. Thus, it is difficult to synthesize a large amount of nanotube-nanohorn complex. Furthermore, if a laser output is 65 kW/cm² or higher, then a nanotube-nanohorn complex 1 can be synthesized. However, amorphous carbon improperly increases.

An irradiation area can be controlled by a laser output and the degree of convergence of a lens. An available irradiation area is in a range of 0.01 cm² to 1 cm².

A laser beam can be emitted in a direction substantially perpendicular to a surface of a carbon target substance or in a direction inclined at an angle less than 90 degrees with respect to the orthogonal line to a surface of a carbon target substance.

### [Carbon Target Containing Catalyst]

A carbon target substance irradiated with a laser beam may contain, as a catalyst, a trace of metal including at least one of Fe, Ni, Co, Pt, Au, Cu, Mo, W, Mg, Pd, Rh, Ti, Nb, Ru, Y, and B, or a precursor thereof, or an alloy thereof. In this case, it is preferable to include a catalyst at an element ratio of 0.1 atomic % to 30 atomic % to carbon. The optimum element ratio is 0.1 atomic % to 5 atomic %. This carbon target substance containing a catalyst is housed in a chamber, and a laser beam is concentrated by a ZnSe lens or the like and emitted to the carbon target substance. At that time, the temperature of the chamber can be adjusted from a room temperature to 1500° C. It is preferable to set the temperature of the chamber at a room temperature in view of mass synthesis, cost reduction, and the like.

### [Atmosphere Gas]

Inert gas, hydrogen, air, carbon monoxide, carbon dioxide, and the like can be introduced into a chamber in which a laser ablation is performed. The gas passes through the chamber, and a flow of the gas allows produced substances to be recovered. A closed atmosphere may be used depending upon the gas being introduced. Ar or Kr is suitable for an atmosphere gas. In a case where an inert gas is used, amorphous carbon tends to be included when the gas has a relatively small atomic weight. Petal-like nanohorns are likely to be produced when the gas has a relatively large atomic weight. The flow rate of the atmosphere gas may be set at any value. Nevertheless, the flow rate of the atmosphere gas is preferably in a range of 0.5 L/min to 100 L/min.

The gas pressure of the chamber after the introduction of the gas is about 0.01 Torr (0.013×10² Pa) to about 760 Torr (1013×10² Pa). At that time, in order to increase a ratio of the carbon nanotube 102, a pressure that is not more than 400 Torr (533×10² Pa) is suitable for the gas pressure of the chamber. In order to increase a ratio of the carbon nanohorn aggregate, it is preferable to set the gas pressure of the chamber at not less than 400 Torr (533×10² Pa).

Thus, according to the present embodiment, the carbon nanotube 102 grows from the catalyst 101 in the nanotube-nanohorn complex 1, and the carbon nanohorn aggregate 100 surrounds the catalyst 101. Therefore, the nanotube-nanohorn complex 1 has a high aspect ratio also has high dispersibility. At the same time, the nanotube-nanohorn complex 1 has controlled diameter and has high durability at a low cost.

Moreover, according to the present embodiment, a nanotube-nanohorn complex 1 is synthesized by evaporating a carbon target containing a catalyst with a laser ablation method.

Accordingly, the nanotube-nanohorn complex 1 comprises an inexpensive structure in which its diameter has been controlled at a desired value.

### EXAMPLES

Examples will be shown below to illustrate and explain the present invention in greater detail. However, the present invention is not limited to the following examples.

### Example 1

A carbon target containing a catalyst was evaporated under a constant gas pressure by a laser ablation method while a laser output was varied. Thus, nanotube-nanohorn complexes 1 were produced by way of trial. The following specific steps were performed.

First, a carbon target containing a catalyst having a diameter of 2.5 cm and a length of 10 cm was placed in a chamber. An inert gas of Ar was supplied so that a gas pressure was 150 Torr (200×10² Pa). The interior of the chamber was held at a room temperature. A flow rate of Ar was set to be 10 L/min. The target containing a catalyst included Co at 0.6 atomic % and Ni at 0.6 atomic %. A target rotation mechanism was provided within the chamber so that a laser beam could continuously be emitted, and was adjusted so that a uniform target surface was produced at the time of continuous emission.

Then the target containing a catalyst was irradiated with a CO₂ laser while the output of the CO₂ laser was set to be 15 kW/cm², 30 kW/cm², 50 kW/cm², 65 kW/cm², and 75 kW/cm², respectively. Samples were synthesized under the respective conditions. Measurement of the Raman spectrum of the obtained samples and observation of surfaces of the obtained samples were conducted.

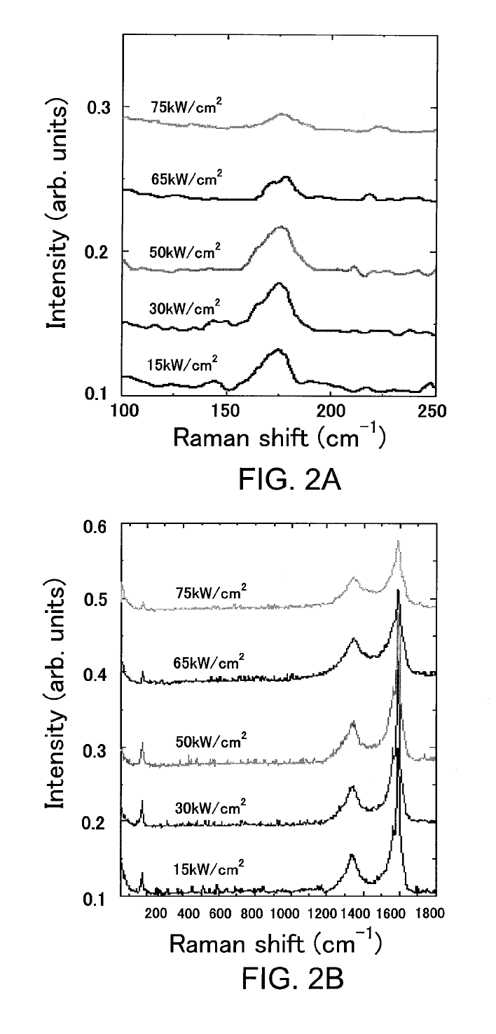

FIGS. 2A and 2B show the results of the Raman spectrum, and FIGS. 1A, 1B, and 3A to 3D show the results of the surface observation.

FIG. 2A illustrates a region of 100 cm⁻¹ to 250 cm⁻¹, which was the region of RBM (Radial Breathing Mode) of carbon nanotubes. The RBM is a mode of vibration in which the diameter of a carbon nanotube expands and contracts in a totally symmetric manner. The amount of shift is roughly in inverse proportion to the diameter of the carbon nanotube. It can be seen that the carbon nanotube was a single layer carbon nanotube in which the diameter distribution was uniform to some degree because there was no peaks other than in the RBM region. Furthermore, FIG. 2B shows a G band (1550 cm⁻¹ to 1590 cm⁻¹), which is a mode of vibration in the plane of a graphene structure, and a D band (1350 cm⁻¹), which is caused by defects. It has been known that a ratio of the G band and the D band is an index indicating the crystallinity. Therefore, it is seen that a ratio of the carbon nanotube increased when the laser output was 30 kW/cm² to 50 kW/cm². Furthermore, it is seen that a carbon nanotube was unlikely to be obtained if the laser output was too high. FIGS. 1A, 1B, and 3A to 3D are diagrams simulating electron microscope photographs and scanning electron microscope photographs of samples obtained under those conditions. It can be seen from those figures and the Raman spectrum results that a nanotube-nanohorn complex (NTNH) in which a single layer carbon nanotube coexists with a carbon nanohorn was synthesized with a uniform diameter. Therefore, it has been revealed that the content of NT (nanotube) in the NTNH can be controlled by a laser output and that the diameter of the nanotube is uniform.

Furthermore, it was confirmed that a G/D ratio of the Raman spectrum of NTNH synthesized under the aforementioned conditions of 30 kW/cm² to 50 kW/cm² was higher than a G/D ratio of NTNH synthesized by a CVD method. It was also confirmed that NTNH synthesized under the aforementioned conditions of 30 kW/cm² to 50 kW/cm² had higher crystallinity.

### Example 2

Under the same conditions as in Example 1 except for a constant laser output (50 kW/cm²) and a varying pressure of Ar, nanotube-nanohorn complexes were produced by way of trial. Measurement of the Raman spectrum of the obtained samples and observation of surfaces of the obtained samples were conducted.

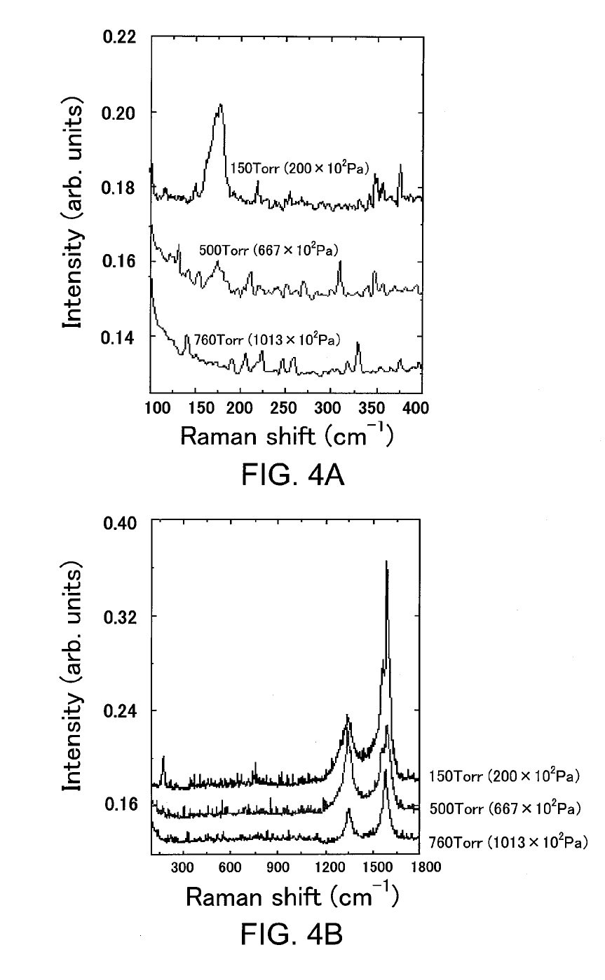

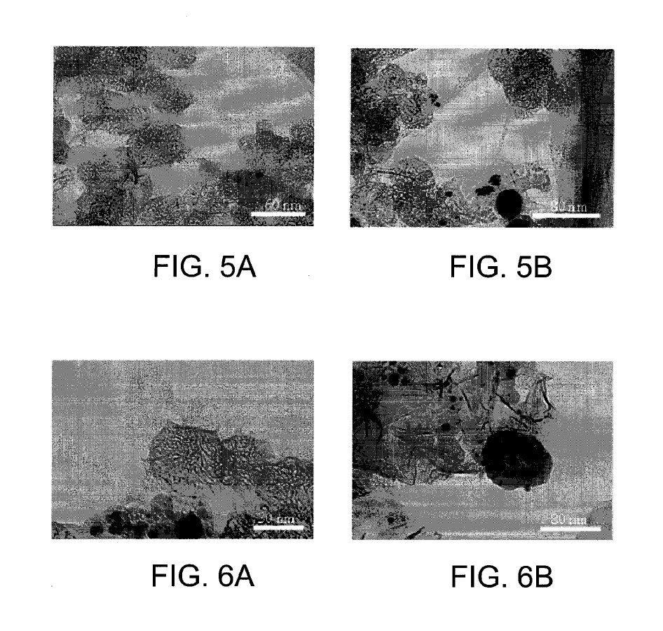

FIGS. 4A and 4B show the results of the Raman spectrum, FIGS. 5A to 6B show the results of the surface observation.

It can be seen from FIG. 4A that the RBM was reduced as the pressure was increased from 150 Torr (200×10² Pa) to 760 Torr (1013×10² Pa). Therefore, it can be seen that the amount of a single layer carbon nanotube was reduced. Furthermore, a G/D ratio of FIG. 4B was also deteriorated, exhibiting the same tendency as the RBM results.

FIGS. 5A and 5B are diagrams simulating transmission electron microscope photographs of samples produced under conditions in which an Ar pressure was 500 Torr (667×10² Pa). It can be seen from those figures that most of the synthesized samples were carbon nanohorns. Fewer carbon nanotubes were included as compared to the case where an Ar pressure was 150 Torr (200×10² Pa).

FIGS. 6A and 6B are diagrams simulating transmission electron microscope photographs of samples produced under conditions in which an Ar pressure was 760 Torr (1013×10² Pa). It can be seen from those figures that most of the synthesized samples were dahlia-like carbon nanohorns or petal-like carbon nanohorns. Few carbon nanotubes were included.

### Example 3

Under the same conditions as in Example 1 except that a catalyst had a different composition with a constant laser output (50 kW/cm²), Ar pressure (150 Torr (200×10² Pa)), and flow rate (10 L/min), nanotube-nanohorn complexes were produced by way of trial. Measurement of the Raman spectrum of the obtained samples was conducted.

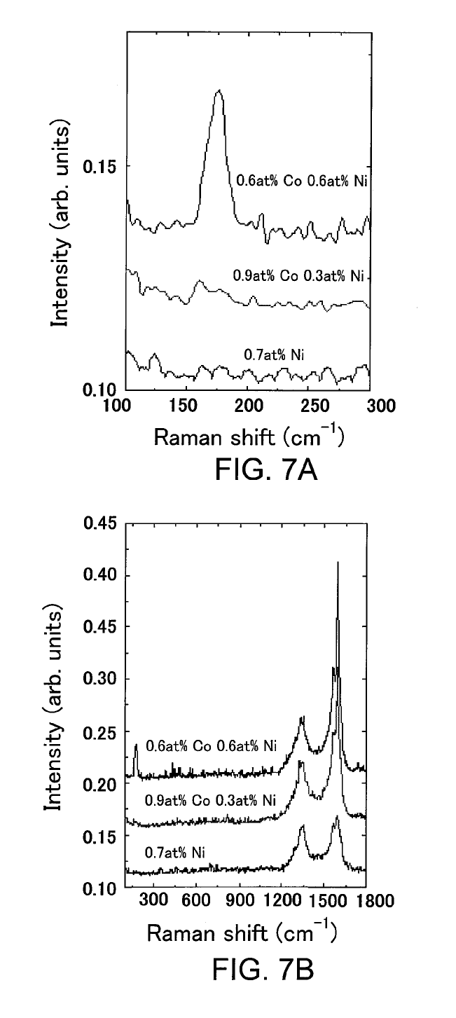

FIGS. 7A and 7B show the results of the Raman spectrum.

It can be seen from FIGS. 7A and 7B that a large number of SWNTs (Single-Walled Carbon Nanotubes) were synthesized in a case where Co:Ni=1:1. Furthermore, it appears that carbon nanotubes were hardly synthesized with only Ni.

### Example 4

Under the same conditions as in Example 1 expect that an Ar gas and a Kr gas were respectively used with a constant laser output (50 kW/cm²), nanotube-nanohorn complexes were produced by way of trial. Measurement of the Raman spectrum of the obtained samples was conducted.

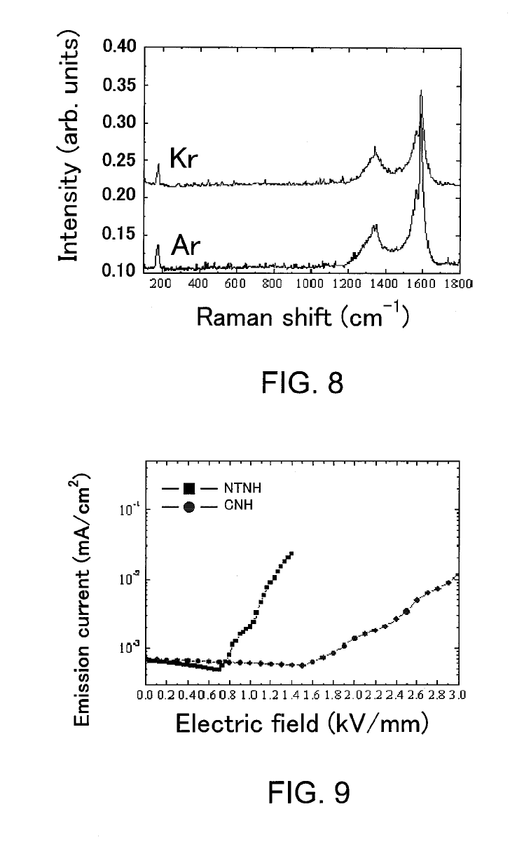

FIG. 8 shows the results.

It can be seen from the RBM of FIG. 8 that the samples had substantially the same diameter. However, it can be seen from G/D ratios of FIG. 8 that the sample produced under the Ar atmosphere had high crystallinity.

### Example 5

Field emission paste was produced using the samples produced with a laser output of 50 kW/cm² among the samples produced in Example 1. The field emission characteristics of the paste were evaluated.

Specifically, the sample was first subjected to ultrasonic dispersion in α-terpineol (15 ml) for 30 minutes. The dispersion was mixed with a cellulose type organic binder of 200 mg and glass frit of 400 mg and then subjected to ultrasonic dispersion for 30 minutes. The paste was screen-printed on a glass substrate on which ITO (Indium Tin Oxide) had been sputtered so that the paste had a thickness of about 100 μm. Thereafter, a heat treatment was performed at 500° C. in nitrogen to remove the organic binder. Furthermore, for a purpose of comparison, paste was produced using only carbon nanohorns in the same manner described above, and an electrode was produced. The current-voltage characteristics of a cathode were measured in a state in which a degree of vacuum was 10⁻⁶ Torr (1.3×10⁻⁴ Pa). FIG. 9 shows the measurement results of the field electron emission characteristics of an electrode using nanotube-nanohorn complexes (NTNH) according to the present embodiment and an electrode using carbon nanohorns (CNH) as a comparative example. A potential of field emission is lower in the electrode using NTNH as compared to the electrode using CNH.

Some or all of the above embodiments can be described as in the following notes. Nevertheless, the present invention is not limited to those notes.

### (Note 1)

A nanotube-nanohorn complex wherein a carbon nanotube grows from a catalyst, which is surrounded by a carbon nanohorn aggregate.

### (Note 2)

The nanotube-nanohorn complex as recited in Note 1, wherein the carbon nanohorns comprise one of a dahlia-like form, a bud-like form, a seed-like form, and a petal-like form.

### (Note 3)

The nanotube-nanohorn complex as recited in one of Notes 1 and 2, wherein the carbon nanotube has a single layer, and the carbon nanotube has a diameter of 0.4 nm to 4 nm

### (Note 4)

The nanotube-nanohorn complex as recited in one of Notes 1 and 2, wherein the carbon nanotube has two layers, and the carbon nanotube has an inside diameter of 0.4 nm to 20 nm and an outside diameter of 0.7 nm to 22 nm.

### (Note 5)

The nanotube-nanohorn complex as recited in one of Notes 1 and 2, wherein the carbon nanotube has multiple layers, and the carbon nanotube has an inside diameter of 0.4 nm to 200 nm and an outside diameter of 0.7 nm to 500 nm.

### (Note 6)

The nanotube-nanohorn complex as recited in one of Notes 1 to 5, wherein the nanotube-nanohorn complex is synthesized by evaporating a carbon target containing a catalyst with a laser ablation method.

### (Note 7)

The nanotube-nanohorn complex as recited in Note 6, wherein the catalyst includes at least one of Fe, Ni, Co, Pt, Au, Cu, Mo, W, Mg, Pd, Rh, Ti, Nb, Ru, Y, and B, or a precursor thereof, or an alloy thereof.

### (Note 8)

The nanotube-nanohorn complex as recited in one of Notes 6 and 7, wherein the nanotube-nanohorn complex is synthesized with a laser output of 1 kW/cm² to 1000 kW/cm².

### (Note 9)

The nanotube-nanohorn complex as recited in one of Notes 6 to 8, wherein the nanotube-nanohorn complex is synthesized by evaporating the carbon target containing the catalyst with the laser ablation method in a gas atmosphere including Ar, N₂, He, Ne, Kr, or Xe, or a mixture gas thereof.

### (Note 10)

The nanotube-nanohorn complex as recited in one of Notes 6 to 9, wherein the nanotube-nanohorn complex is synthesized by evaporating the carbon target containing the catalyst with the laser ablation method in a gas atmosphere at a pressure of 0.01 Torr to 760 Torr (0.013×10² Pa to 1013×10² Pa).

### (Note 11)

The nanotube-nanohorn complex as recited in one of Notes 6 to 10, wherein the nanotube-nanohorn complex is synthesized by evaporating the carbon target containing the catalyst with the laser ablation method in a gas atmosphere at a gas flow rate of 0.1 L/min to 100 L/min.

### (Note 12)

A method of manufacturing a nanotube-nanohorn complex, the method comprising evaporating a carbon target containing a catalyst with a laser ablation method to synthesize a structure including both of a carbon nanohorn aggregate and a carbon nanotube.

### (Note 13)

A method of manufacturing a nanotube-nanohorn complex, the method comprising evaporating a carbon target containing a catalyst with a laser ablation method to synthesize a structure in which a carbon nanotube grows from the catalyst, which is surrounded by a carbon nanohorn aggregate.

### (Note 14)

The method of manufacturing a nanotube-nanohorn complex as recited in one of Notes 12 and 13, wherein the carbon nanohorns comprise one of a dahlia-like form, a bud-like form, a seed-like form, and a petal-like form.

### (Note 15)

The method of manufacturing a nanotube-nanohorn complex as recited in one of Notes 12 to 14, wherein the carbon nanotube has a single layer, and the carbon nanotube has a diameter of 0.4 nm to 4 nm.

### (Note 16)

The method of manufacturing a nanotube-nanohorn complex as recited in one of Notes 12 to 14, wherein the carbon nanotube has two layers, and the carbon nanotube has an inside diameter of 0.4 nm to 20 nm and an outside diameter of 0.7 nm to 22 nm.

### (Note 17)

The method of manufacturing a nanotube-nanohorn complex as recited in one of Notes 12 to 14, wherein the carbon nanotube has multiple layers, and the carbon nanotube has an inside diameter of 0.4 nm to 200 nm and an outside diameter of 0.7 nm to 500 nm.

### (Note 18)

The method of manufacturing a nanotube-nanohorn complex as recited in one of Notes 12 to 17, wherein the catalyst of the carbon target containing the catalyst includes at least one of Fe, Ni, Co, Pt, Au, Cu, Mo, W, Mg, Pd, Rh, Ti, Nb, Ru, Y, and B, or a precursor thereof, or an alloy thereof.

### (Note 19)

The method of manufacturing a nanotube-nanohorn complex as recited in one of Notes 12 to 18, wherein the laser ablation method is performed with a laser output of 1 kW/cm² to 1000 kW/cm².

### (Note 20)

The method of manufacturing a nanotube-nanohorn complex as recited in one of Notes 12 to 19, wherein the laser ablation method is performed in a gas atmosphere including Ar, N₂, He, Ne, Kr, or Xe, or a mixture gas thereof.

### (Note 21)

The method of manufacturing a nanotube-nanohorn complex as recited in one of Notes 12 to 20, wherein the laser ablation method is performed in a gas atmosphere at a pressure of 0.01 Torr to 760 Torr (0.013×10² Pa to 1013×10² Pa).

### (Note 22)

The method of manufacturing a nanotube-nanohorn complex as recited in one of Notes 12 to 21, wherein the laser ablation method is performed in a gas atmosphere at a gas flow rate of 0.1 L/min to 100 L/min.

### (Note 23)

A paste for field emission comprising the nanotube-nanohorn complex as recited in one of Notes 1 to 11.

### (Note 24)

A cold cathode electron source comprising the paste for field emission as recited in Note 23.

### (Note 25)

A light emitting device using the cold cathode electron source as recited in Note 24.

### (Note 26)

An illuminating apparatus using the light emitting device as recited in Note 25.

### (Note 27)

A light emitting method using the illuminating apparatus as recited in Note 26.

In the aforementioned embodiments and examples, the nanotube-nanohorn complex is used as a material of paste for field emission. However, the present invention is not limited to this example at all and is applicable to any structure using a nanotube-nanohorn complex.

Furthermore, paste field emission according to the present invention is applicable to a cold cathode electron source or a light emitting device such as an illuminating device using such a cold cathode electron source.

This application is based upon and claims the benefit of priority from Japanese patent application No. 2009-238936, filed on Oct. 16, 2009, the disclosure of which is incorporated herein in its entirety by reference.

1. A nanotube-nanohorn complex wherein a carbon nanotube grows from a catalyst, which is surrounded by a carbon nanohorn aggregate.

2. The nanotube-nanohorn complex as recited in claim 1, wherein the carbon nanohorns comprise one of a dahlia-like form, a bud-like form, a seed-like form, and a petal-like form.

3. The nanotube-nanohorn complex as recited in claim 1, wherein the carbon nanotube has a single layer, and the carbon nanotube has a diameter of 0.4 nm to 4 nm.

4. The nanotube-nanohorn complex as recited in claim 1, wherein the carbon nanotube has two layers, and the carbon nanotube has an inside diameter of 0.4 nm to 20 nm and an outside diameter of 0.7 nm to 22 nm.

5. The nanotube-nanohorn complex as recited in claim 1, wherein the carbon nanotube has multiple layers, and the carbon nanotube has an inside diameter of 0.4 nm to 200 nm and an outside diameter of 0.7 nm to 500 nm.

6. The nanotube-nanohorn complex as recited in claim 1, wherein the nanotube-nanohorn complex is synthesized by evaporating a carbon target containing a catalyst with a laser ablation method.

7. The nanotube-nanohorn complex as recited in claim 6, wherein the catalyst includes at least one of Fe, Ni, Co, Pt, Au, Cu, Mo, W, Mg, Pd, Rh, Ti, Nb, Ru, Y, and B, or a precursor thereof, or an alloy thereof.

8. The nanotube-nanohorn complex as recited in claim 6, wherein the nanotube-nanohorn complex is synthesized with a laser output of 1 kW/cm² to 1000 kW/cm².

9. The nanotube-nanohorn complex as recited in claim 6, wherein the nanotube-nanohorn complex is synthesized by evaporating the carbon target containing the catalyst with the laser ablation method in a gas atmosphere including Ar, N₂, He, Ne, Kr, or Xe, or a mixture gas thereof.

10. (canceled)

11. (canceled)

12. A method of manufacturing a nanotube-nanohorn complex, the method comprising evaporating a carbon target containing a catalyst with a laser ablation method to synthesize a structure including both of a carbon nanohorn aggregate and a carbon nanotube.

13. A method of manufacturing a nanotube-nanohorn complex, the method comprising evaporating a carbon target containing a catalyst with a laser ablation method to synthesize a structure in which a carbon nanotube grows from the catalyst, which is surrounded by a carbon nanohorn aggregate.

14. The method of manufacturing a nanotube-nanohorn complex as recited in claim 12, wherein the carbon nanohorns comprise one of a dahlia-like form, a bud-like form, a seed-like form, and a petal-like form.

15. The method of manufacturing a nanotube-nanohorn complex as recited in claim 12, wherein the carbon nanotube has a single layer, and the carbon nanotube has a diameter of 0.4 nm to 4 nm.

16. The method of manufacturing a nanotube-nanohorn complex as recited in claim 12, wherein the carbon nanotube has two layers, and the carbon nanotube has an inside diameter of 0.4 nm to 20 nm and an outside diameter of 0.7 nm to 22 nm.

17. The method of manufacturing a nanotube-nanohorn complex as recited in claim 12, wherein the carbon nanotube has multiple layers, and the carbon nanotube has an inside diameter of 0.4 nm to 200 nm and an outside diameter of 0.7 nm to 500 nm.

18. The method of manufacturing a nanotube-nanohorn complex as recited in claim 12, wherein the catalyst of the carbon target containing the catalyst includes at least one of Fe, Ni, Co, Pt, Au, Cu, Mo, W, Mg, Pd, Rh, Ti, Nb, Ru, Y, and B, or a precursor thereof, or an alloy thereof.

19. The method of manufacturing a nanotube-nanohorn complex as recited in claim 12, wherein the laser ablation method is performed with a laser output of 1 kW/cm² to 1000 kW/cm².

20. The method of manufacturing a nanotube-nanohorn complex as recited in claim 12, wherein the laser ablation method is performed in a gas atmosphere including Ar, N₂, He, Ne, Kr, or Xe, or a mixture gas thereof

21. The method of manufacturing a nanotube-nanohorn complex as recited in claim 12, wherein the laser ablation method is performed in a gas atmosphere at a pressure of 0.01 Torr to 760 Torr (0.013×10² Pa to 1013×10² Pa).

22. The method of manufacturing a nanotube-nanohorn complex as recited in claim 12, wherein the laser ablation method is performed in a gas atmosphere at a gas flow rate of 0.1 L/min to 100 L/min.

23. (canceled)

24. (canceled)

25. (canceled)

26. (canceled)

27. (canceled)
